(19) United States
(12) Patent Application Publication
(10) Pub. No.: US 2013/0323916 A1
(43) Pub. Date: Dec. 5, 2013

(54) PLASMA DOPING METHOD AND APPARATUS

(71) Applicant: PANASONIC CORPORATION, Osaka (JP)

(72) Inventors: Tomohiro OKUMURA, Osaka (JP); Yuichiro SASAKI, Tokyo (JP); Katsumi OKASHITA, Osaka (JP); Bunji MIZUNO, Nara (JP); Hiroyuki ITO, Chiba (JP); Ichiro NAKAYAMA, Osaka (JP); Cheng-Guo JIN, Osaka (JP)

(73) Assignee: PANASONIC CORPORATION, Osaka (JP)

(21) Appl. No.: 13/682,531

(22) Filed: Nov. 20, 2012

Related U.S. Application Data
(62) Division of application No. 11/887,381, filed on Nov. 5, 2008, now abandoned.

(30) Foreign Application Priority Data
Mar. 30, 2005 (JP) 2005-099103

(51) Int. Cl. H01L 21/223

(52) U.S. Cl. CPC H01L 21/2236
USPC 438/513

(57) ABSTRACT

A plasma doping apparatus which introduces a predetermined mass flow of gas from a gas supply device into a vacuum chamber while discharging the gas through an exhaust port by a turbo-molecular pump, which is an exhaust device in order to maintain the vacuum chamber under a predetermined pressure by a pressure adjusting valve. A high-frequency power source supplies high-frequency power of 13.56 MHz to a coil disposed in the vicinity of a dielectric window opposite a sample electrode in order to generate an inductively coupled plasma in the vacuum chamber. A sum of an area of an opening of a gas flow-off port opposed to a center portion of the sample electrode is configured to be smaller than that of an area of an opening of the gas flow-off port opposed to a peripheral portion of the sample electrode in order to improve the uniformity.

### TECHNICAL FIELD

The present invention relates to plasma doping method and an apparatus for introducing impurities into a surface of a solid sample such as a semiconductor substrate.

### BACKGROUND ART

As a technique of introducing impurities into a surface of a solid sample, there is known a plasma doping method of ionizing the impurities and introducing them into a solid at low energy (for example, see Patent Document 1). FIG. 9 is a diagram illustrating an overall configuration of a plasma doping apparatus used for the plasma doping method as the known method of introducing the impurities disclosed in Patent Document 1. In FIG. 9, a sample electrode 6 for placing a sample 9 formed of a silicon substrate is provided in the inside of a vacuum chamber 1. In the vacuum chamber 1, a gas supply device 2 for supplying doping material gases including a desired element, for example, B₂H₆ and a pump 3 for depressurizing the inside of the vacuum chamber 1 are provided so as to allow the inside of the vacuum chamber 1 to be maintained under a predetermined pressure. Microwaves are radiated from a microwave waveguide 31 to the inside of the vacuum chamber 1 through a quartz plate 32 that is a dielectic window. An interaction between the microwaves and direct current created by an electrical magnet 33 induces a microwave plasma (electron cyclotron resonance plasma) 34 with a magnetic field to be formed in the inside of the vacuum chamber 1. A high-frequency power source 10 is connected to the sample electrode 6 through a capacitor 35 so as to control a potential of the sample electrode 6. Gases supplied from the gas supply device 2 are introduced from a gas flow-off port 36 to the inside of the vacuum chamber 1 and evacuated from an exhaust port 11 to the pump 3.

In the plasma doping apparatus having such a configuration, a doping material gas, for example, B₂H₆ introduced from the gas introducing port 36 is plasmarized by plasma generating means including the microwave waveguide 31 and the electrical magnet 33 and born ions in the plasma 34 are introduced into a surface of the sample 9 by the high-frequency power source 10.

When a metal wiring layer is formed on the sample 9 in which the impurities are introduced in this way, a thin oxide film is formed on the metal wiring layer in a predetermined oxidation atmosphere, and a gate electrode is formed on the sample 9 by a CVD device or the like, it is possible to obtain, for example, an MOS transistor.

Meanwhile, in a field related to a normal plasma doping apparatus, an inductively coupled type plasma doping apparatus provided with a plurality of gas flow-off ports arranged to be opposed to a sample was developed (for example, see Patent Document 2). FIG. 10 is a diagram illustrating an overall configuration of a known dry etching device disclosed in Patent Document 2. In FIG. 10, a top wall of a vacuum-processing chamber 1 includes a first top plate 7, which is an upper portion formed of a dielectric, and a second top plate 41, which is a lower portion. In addition, multiple coils 8 which are arranged on the first top plate 2 are connected to a high-frequency power source 5. Process gases are configured to be supplied toward the first top plate 7 from a gas introducing passage 13. A gas primary passage 14 including one or plurality of cavities passing through one inside point is formed on the first top plate 7 so as to communicate with the gas introducing passage 13. In addition, gas flow-off holes 42 are formed on the first top plate 7 so as to reach from a bottom surface of the top plate 7 to the gas primary passage 14. On the second top plate 41, gas flowing through-holes 43 are formed in positions equal to the gas flow-off holes 42. The vacuum-processing chamber 1 is configured so that the gases can be evacuated through an exhaust passage 44. In addition, a substrate stage 6 is disposed on a lower portion of the vacuum-processing chamber 1 so that a substrate 9 to be processed is maintained thereon.

With such a configuration, when the substrate 9 is processed, the substrate 9 is placed on the substrate stage 6 and a vacuum discharging is performed through the exhaust passage 44. After the vacuum discharging, the process gases necessary for a plasma process are introduced from the gas introducing passage 13. The process gases pass through the gas primary passage 14 disposed in the first top plate 7, uniformly spread out in the inside of the first top plate 7, pass through the gas flow-off holes 42, uniformly reach a boundary between the first top plate 7 and the second top plate 41, pass through the gas flowing through-holes 43 disposed in the second plate 41, and uniformly distribute on the substrate 9. By applying high-frequency power from a high-frequency power source 5 to coils 8, the gases in the vacuum processing chamber 1 are excited by electromagnetic waves radiated from the coils 8 to the inside of the vacuum-processing chamber 1. In addition, the substrate 9 placed on the sample electrode 5, which is the substrate stage in the vacuum processing chamber 1, is processed by a plasma generated in the lower portions of the top plates 7 and 41.
Patent Document 1: U.S. Pat. No. 4,912,065
Patent Document 2: Japanese Patent Unexamined Publication No. 2001-15493

### DISCLOSURE OF THE INVENTION

### Problem to be Solved by the Invention

However, in the known examples, a problem arises in that in-plane uniformity of an amount of introduced impurities (amount of dose) is poor. Since the gas flow-off ports 36 are anisotropically arranged, portions close to the gas flow-off ports 36 have much amount of dose, but portions away the gas flow-off ports 36 have small amount of dose.

Accordingly, a plasma doping was tried using the plasma doping apparatus disclosed in Patent Document 2, but the amount of dose in the center portion of the substrate is larger and the amount of dose in the peripheral portion of the substrate is smaller, thereby resulting in poor uniformity.

The present invention is contrived in consideration of the above-described problem and an object of the invention is to provide a plasma doping method and apparatus in which concentration of impurities introduced into a sample surface is excellent.

### Means for Solving the Problem

According to an aspect of the invention, there is a provided a plasma doping method including the steps of placing a sample on a sample electrode in a vacuum chamber; flowing a gas substantially isotropically toward the sample from a surface opposed to the sample while discharging the gas in the vacuum chamber; generating a plasma in the vacuum chamber while controlling the vacuum chamber to be under a predetermined pressure; and introducing impurity ions into a surface of the sample by allowing the impurity ions in the plasma to collide with the surface of the sample, wherein a mass flow of gas flown toward a center portion of the sample is smaller than that of gas flown toward a peripheral portion of the sample.

With such a configuration, it is possible to realize the plasma doping method in which uniformity of concentration of the impurities introduced into the surface of the sample is excellent.

In the plasma doping method with the above-described configuration, the center portion of the sample may be defined as a portion of which an area is a half of that of the sample and which includes a center of the sample, and the peripheral portion of the sample may be defined as the other portion of the sample and which does not include the center of the sample.

In the plasma doping method with the above-described configuration, the mass flow of gas flown toward the center of the sample may be a half or less than that of gas flown toward the peripheral portion of the sample. With such a configuration, it is possible to realize the plasma doping method in which the uniformity of the concentration of the impurities introduced into the surface of the sample is further excellent.

According to another aspect of the invention, there is provided a plasma doping method including the steps of placing a sample on a sample electrode in a vacuum chamber; flowing a gas substantially isotropically toward the sample from a surface opposed to the sample while discharging the gas in the vacuum chamber; generating a plasma in the vacuum chamber while controlling the vacuum chamber to be under a predetermined pressure; and introducing impurity ions into a surface of the sample by allowing the impurity ions in the plasma to collide with the surface of the sample, wherein a mass flow of gas flown toward the sample is less than that of gas flown toward the outside of the sample in a surface on which the sample is placed.

With such a configuration, it is possible to realize the plasma doping method in which the uniformity of the concentration of the impurities introduced into the surface of the sample is excellent.

In the plasma doping method with the above-described configuration, the mass flow of gas flown toward the sample may be a half or less than that of gas flown toward the outside of the sample in the surface on which the sample is placed. With such a configuration, it is possible to realize the plasma doping method in which the uniformity of the concentration of the impurities introduced into the surface of the sample is further excellent.

According to still another aspect of the invention, there provided a plasma doping method including the steps of: placing a sample on a sample electrode in a vacuum chamber; flowing a gas substantially isotropically toward the sample from a surface opposed to the sample while discharging the gas in the vacuum chamber; generating a plasma in the vacuum chamber while controlling the vacuum chamber to be under a predetermined pressure; and introducing impurity ions into a surface of the sample by allowing the impurity ions in the plasma to collide with the surface of the sample, wherein a mass flow of gas flown toward a center portion of the sample and a mass flow of gas flown toward a peripheral portion of the sample are controlled by individual mass flow control systems, and wherein a mass flow of impurity material gas included in the gas flown toward the center portion of the sample is less than that of impurity material gas included in the gas flown toward the peripheral portion of the sample.

With such a configuration, it is possible to realize the plasma doping method in which the uniformity of the concentration of the impurities introduced into the surface of the sample is excellent.

In the plasma doping method with the above-described configuration, the center portion of the sample may be defined as a portion of which an area is a half of that of the sample and which includes a center of the sample, and the peripheral portion may be defined as the other portion of the sample and which does not include the center of the sample.

In the plasma doping method with the above-described configuration, the mass flow of impurity material gas flown toward the center portion of the sample is a half or less than that of impurity material gas included in the gas flown toward the peripheral portion of the sample. With such a configuration, it is possible to realize the plasma doping method in which the uniformity of the concentration of the impurities introduced into the surface of the sample is further excellent.

According to still another aspect of the invention, there is provided a plasma doping method including the steps of placing a sample on a sample electrode in a vacuum chamber; flowing a gas substantially isotropically toward the sample from a surface opposed to the sample while discharging the gas in the vacuum chamber; generating a plasma in the vacuum chamber while controlling the vacuum chamber to be under a predetermined pressure; and introducing impurity ions into a surface of the sample by allowing the impurity ions in the plasma to collide with the surface of the sample, wherein a mass flow of gas flown toward a center portion of the sample and a mass flow of gas flown toward the outside of the sample in a surface on which the sample is placed are controlled by individual mass flow control systems, and wherein an mass flow of impurity material gas included in the gas flown toward the center portion of the sample is less than that of impurity material gas included in the gas flown toward the outside of the sample in the surface on which the sample is placed.

With such a configuration, it is possible to realize the plasma doping method in which the uniformity of the concentration of the impurities introduced into the surface of the sample is excellent.

In the plasma doping method with the above-described configuration, the mass flow of impurity material gas included in the gas flown toward the center portion of the sample may be a half or less than that of impurity material gas included in the gas flown toward the peripheral portion of the sample. With such a configuration, it is possible to realize the plasma doping method in which the uniformity of the concentration of the impurities introduced into the surface of the sample is excellent.

In the plasma doping method with the above-described configuration, plasmas may be generated in the vacuum chamber by the supply of high-frequency power to a plasma source. With such a configuration, it is possible to perform the plasma doping at a high speed while ensuring the uniformity of the concentration of the impurity introduced into the surface of the sample.

In the plasma doping method with the above-described configuration, the sample may be a semiconductor substrate made of silicon. Moreover, the impurity may be arsenic, phosphorous, boron, or antimony.

With such a configuration, it is possible to manufacture a highly minute silicon semiconductor device.

According to still another aspect of the invention, there is provided a plasma doping apparatus including: a vacuum chamber; a sample electrode; a gas supply device supplying a gas in the vacuum chamber; a plurality of gas flow-off ports connected to the gas supply device and provided so as to be opposed to the sample electrode; an exhaust device discharging the gas in the vacuum chamber; a pressure control device controlling pressure of the vacuum chamber; and a sample electrode power source for supplying power to the sample electrode, wherein the plurality of gas flow-off ports are arranged substantially isotropically and a sum of areas of openings of the gas flow-off ports disposed toward a center portion of the sample electrode is smaller than that of areas of openings of the gas flow-off ports disposed toward a peripheral portion of the sample electrode.

With such a configuration, it is possible to realize the plasma doping apparatus in which the uniformity of the concentration of the impurities introduced into the surface of the sample is excellent.

In the plasma doping apparatus with the above-described configuration, the areas of the openings of the gas flow-off ports may be substantially equal to each other, and the number of the gas flow-off ports disposed toward the center portion of the sample electrode may be smaller than that of the gas flow-off ports disposed toward the peripheral portion of the sample electrode. With such a configuration, it is possible to suppress an abnormal evacuation while ensuring the uniformity of the concentration of the impurities introduced into the surface of the sample.

In the plasma doping apparatus with the above-described configuration, the center portion of the sample electrode may be defined as a portion of which an area is a half of that of the sample electrode and which include a center of the sample electrode, and the peripheral portion of the sample electrode may be defined as the other portion of the sample electrode and which does not include the center of the sample electrode.

In the plasma doping apparatus with the above-described configuration, a sum of areas of the openings of the gas flow-off ports disposed toward the center portion of the sample electrode may be a half or less than that of areas of the openings of the gas flow-off ports disposed toward the peripheral portion of the sample electrode. With such a configuration, it is possible to realize the plasma doping apparatus in which the uniformity of the concentration of the impurities introduced into the surface of the sample is further excellent.

According to still another aspect of the invention, there is provided a plasma doping apparatus including a vacuum chamber; a sample electrode; a gas supply device supplying a gas in the vacuum chamber; a plurality of gas flow-off ports connected to the gas supply device and provided so as to be opposed to the sample electrode; an exhaust device discharging the gas in the vacuum chamber; a pressure control device controlling pressure of the vacuum chamber; and a sample electrode power source for supplying power to the sample electrode, wherein the plurality of gas flow-off ports are arranged substantially isotropically and a sum of areas of openings of the gas flow-off ports disposed toward a center portion of the sample electrode is smaller than that of areas of openings of the gas flow-off ports disposed toward the outside of the sample electrode in a surface on which the sample electrode is disposed.

In the plasma doping apparatus with the above-described configuration, the areas of the openings of the gas flow-off ports may be substantially equal to each other, and the number of the gas flow-off ports opposed to the sample electrode may be smaller than that of the gas flow-off ports opposed to the outside of the sample electrode in the surface on which the sample electrode is disposed. With such a configuration, it is possible to suppress the abnormal evacuation while ensuring the uniformity of the concentration of the impurities introduced into the surface of the sample.

Moreover, a sum of areas of the openings of the gas flow-off ports opposed to the sample electrode may be a half or less than that of areas of the openings of the gas flow-off ports opposed to the outside of the sample electrode in the surface on which the sample electrode is disposed. With such a configuration, it is possible to realize the plasma doping apparatus in which the uniformity of the concentration of the impurities introduced into the surface of the sample is further excellent.

According to still another aspect of the invention, there is provided a plasma doping apparatus including a vacuum chamber; a sample electrode; first and second gas supply devices each supplying a gas in the vacuum chamber; a gas flow-off port connected to the first gas supply device and provided so as to be opposed to a center portion of the sample electrode; a gas flow-off port connected to the second gas supply device and provided so as to be opposed to a peripheral portion of the sample electrode; an exhaust device discharging the gas in the vacuum chamber; a pressure control device controlling pressure of the vacuum chamber; and a sample electrode power source for supplying power to the sample electrode, wherein the gas flow-off ports are disposed substantially isotropically.

In the plasma doping apparatus with the above-described configuration, the center portion of the sample electrode may be defined as a portion of which an area is a half of that of the sample electrode and which include a center of the sample electrode, and the peripheral portion of the sample electrode may be defined as the other portion of the sample electrode and which does not include the center of the sample electrode.

According to still another aspect of the invention, there is provided a plasma doping apparatus including: a vacuum chamber; a sample electrode; first and second gas supply devices each supplying a gas in the vacuum chamber; a gas flow-off port connected to the first gas supply device and provided so as to be opposed to the sample electrode; a gas flow-off port connected to the second gas supply device and provided so as to be opposed to the outside of the sample electrode in a surface on which the sample electrode is disposed; an exhaust device discharging the gas in the vacuum chamber; a pressure control device controlling pressure of the vacuum chamber; and a sample electrode power source for supplying power to the sample electrode, wherein the gas flow-off ports are disposed substantially isotropically.

The plasma doping apparatus with the above-described configuration may further include a plasma source and a plasma source high-frequency power source supplying high-frequency power to the plasma source. With such a configuration, it is possible to perform the plasma doping at the high speed while ensuring the uniformity of the concentration of the impurity introduced into the surface of the sample.

### BRIEF DESCRIPTION OF THE DRAWINGS

FIG. 1 is a sectional view illustrating a configuration of a plasma doping to chamber according to Embodiment 1 of the invention.

FIG. 2 is a top view illustrating a configuration of a dielectric window according to Embodiment 1 of the invention.

FIG. 3 is a top view illustrating the configuration of the dielectric window according to Embodiment 1 of the invention.

FIG. 4 is a sectional view illustrating a configuration of a plasma doping chamber according to Embodiment 2 of the invention.

FIG. 5 is a top view illustrating a configuration of a dielectric window according to Embodiment 2 of the invention.

FIG. 6 is a top view illustrating the configuration of the dielectric window according to Embodiment 2 of the invention.

FIG. 7 is a sectional view illustrating a configuration of a plasma doping chamber according to Embodiment 3 of the invention.

FIG. 8 is a sectional view illustrating a configuration of a plasma doping chamber according to Embodiment 4 of the invention.

FIG. 9 is a sectional view illustrating a configuration of a plasma doping chamber used in a known example.

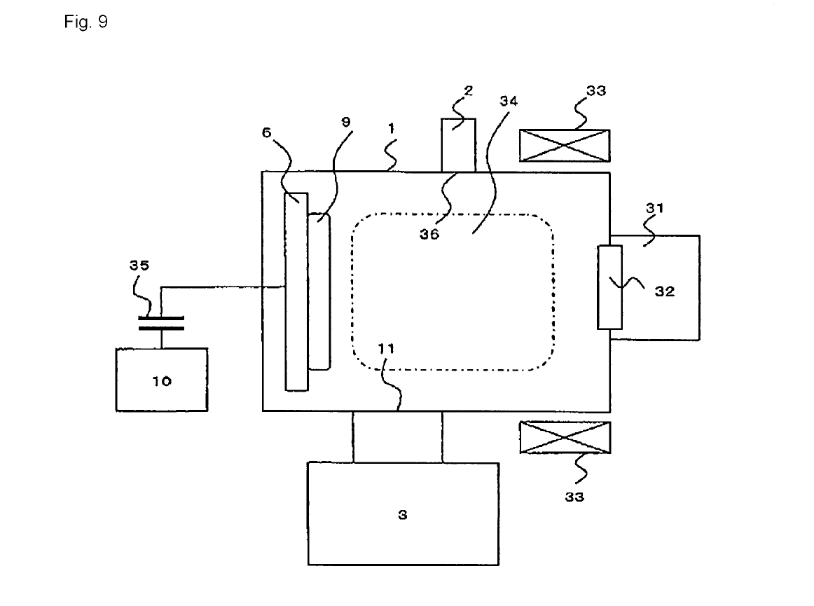

FIG. 10 is a section view illustrating a configuration a dry etching apparatus used in a known example.

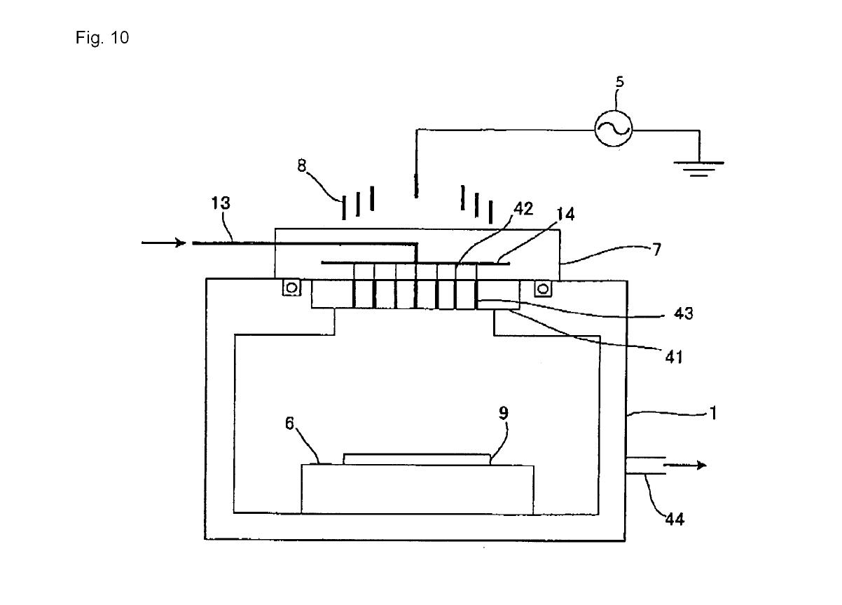

### DESCRIPTION OF REFERENCE NUMERALS AND SIGNS

1: VACUUM CHAMBER
2: GAS SUPPLY DEVICE
3: TURBO-MOLECULAR PUMP
4: PRESSURE ADJUSTING VALVE
5: PLASMA SOURCE HIGH-FREQUENCY POWER SOURCE
6: SAMPLE ELECTRODE
7: DIELECTRIC WINDOW
8: COIL
9: SUBSTRATE
10: SAMPLE ELECTRODE HIGH-FREQUENCY POWER SOURCE
11: EXHAUST PORT
12: SUPPORT
13: GAS INTRODUCING PASSAGE
14: GAS PRIMARY PASSAGE
15: GAS FLOWOFF PORT

### PREFERRED EMBODIMENTS FOR CARRYING OUT THE INVENTION

Hereinafter, embodiments of the invention will be described in detail with reference to the drawings.

### Embodiment 1

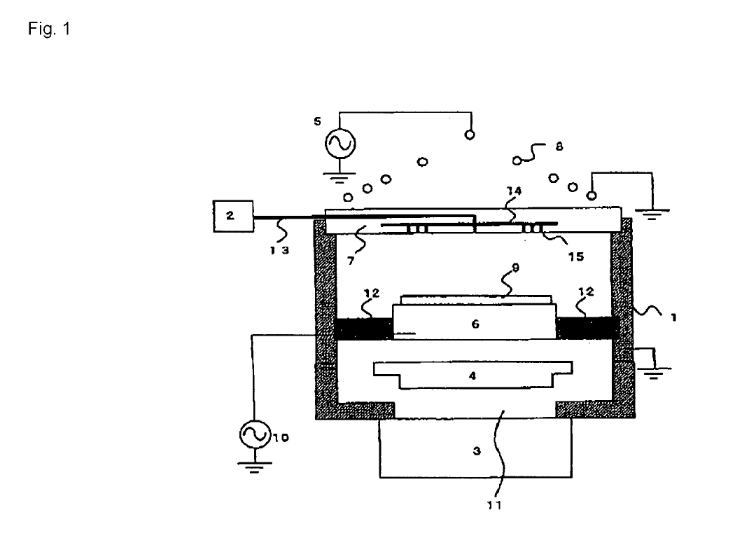

Hereinafter, Embodiment 1 of the invention will be described with reference to FIGS. 1 to 3.

FIG. 1 is a sectional view illustrating a configuration of a plasma doping apparatus according to Embodiment 1 of the invention. In FIG. 1, predetermined gases are introduced into a vacuum chamber 1 from a gas supply device 2 while the gases are evacuated by turbo-molecular a pump 3, which is an exhaust device. In addition, the vacuum chamber 1 can be maintained under a predetermined pressure by a pressure adjusting valve 4. An inductively coupled plasma can be generated by supplying high-frequency power of 13.5 MHz to coils 8 (of which sectional surfaces are shown in FIG. 1) provided in the vicinity of a dielectric window 7 opposed to a sample electrode 6 by a high-frequency power source 5. A silicon substrate 9, which is a sample, is placed on the sample electrode 6. There is provided a high-frequency power source 10 for supplying high-frequency power to the sample electrode 6, which functions as a voltage source for controlling a potential of the sample electrode 6 so as to allow the substrate 9, which is a sample, to have a negative potential relative to a plasma. In this way, impurities can be introduced into a surface of the sample by accelerating ions in plasma toward the surface of the sample to collide with the surface of the sample. Gases supplied from the gas supply device 2 are evacuated from an exhaust port 11 to the pump 3. The turbo-molecular pump 3 and the exhaust port 11 are disposed right below the sample electrode 6. The pressure adjusting valve 4 is an elevation valve which is disposed right below the sample electrode 6 and right above the turbo-molecular pump 3. The sample electrode 6 serves as a substantial rectangle-shaped seat for allowing the substrate 9 to be placed thereon and each side thereof is fixed on the vacuum chamber 1 by a supports 12, that is, the sample electrode 6 is fixed on the vacuum chamber 1 by the total 4 supports 12.

A mass flow control device (mass flow controller), which is disposed in the gas supply device 2, controls mass flow of gas including impurity material gases to be under a predetermined value. Generally, gases diluted with helium, that is, the gases generated by diluting, for example, diborane (B2H6) with helium (He) by 0.5% are used as impurity material gases, which are controlled by a first mass flow controller. A mass flow of helium is controlled by the second mass flow controller, the mass flow of gas controlled by the first and second mass flow controllers are mixed in the gas supply device 2 and guided to the gas primary passage 14 through a pipe (gas introducing passage) 13, and the mixed gases are guided from gas flow-off ports 15 to the inside of the vacuum chamber 1 through a plurality of holes communicating with the gas primary passage 14. A plurality of the gas flow-off ports 15 are configured to flow off gases toward the sample 9 from a surface opposite the sample 9.

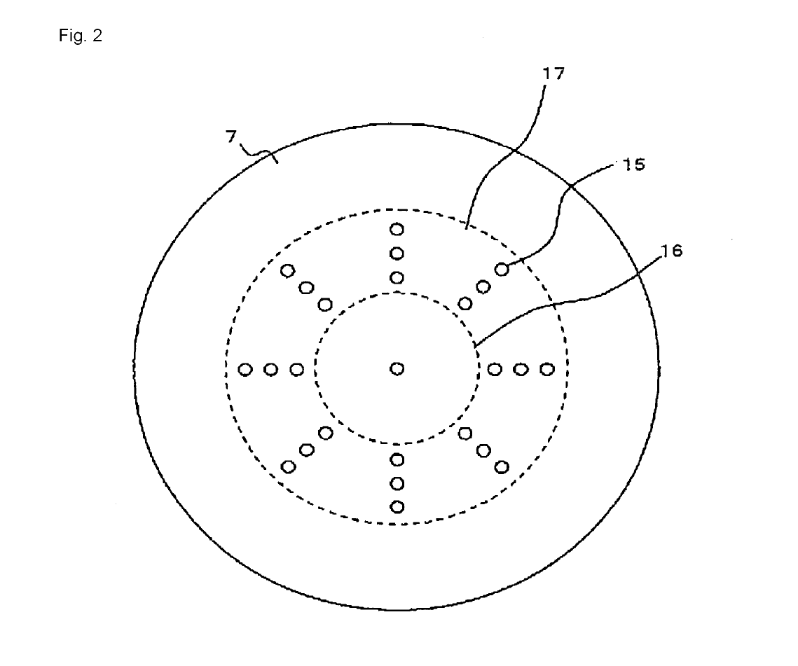

FIG. 2 is a top view illustrating the dielectric window 7 when viewed from a lower side in FIG. 1. As shown in FIG. 2, the gas flow-off ports 15 are arranged so as to be substantially symmetric about the center of the dielectric window 7 and configured so as to flow off the gases substantially isotropically toward the sample. That is, the plurality of gas flow-off ports 15 are arranged substantially isotropically. “A center portion of the sample (electrode)” is defined as “a portion of which an area is a half of that of the sample (electrode) and which include the center of the sample (electrode)”. In addition, “a peripheral portion of the sample (electrode)” is defined as “a portion which is the other portion of the sample (electrode) and which does not include the center of the sample (electrode). At this time, the gas flow-off port arranged to be opposed to the center portion of the sample electrode are considered to be the gas flow-off port (1 port) arranged in the inside of an inner circle 16 (which is a circle with a (½)^{1/2} of the diameter of the sample). In addition, the gas flow-off ports arranged to be opposed to the peripheral portion of the sample is considered to be the gas flow-off ports (24 ports) arranged in the inside of an outer circle 17 (which is a circle with the same diameter as that of the sample) and the outside of the inner circle 16. In this way, areas of openings of the gas flow-off ports 15 are configured so as to be substantially equal to each other and the number of the gas flow-off ports 15 arranged to be opposed to the center portion of the sample electrode 6 is smaller than that of the flow-off ports arranged to be opposed to the peripheral portion of the sample electrode 6. Accordingly, the mass flow of gas flown toward the center portion of the sample 9 can be smaller than that of gas flown toward the peripheral portion of the sample 9.

The plasma was generated in the vacuum chamber 1 by supplying B₂H₆ gases of 5 sccm diluted with He and He gases of 100 sccm while allowing a temperature of the sample electrode 6 to be maintained at 25° C. and supplying high-frequency power of 1300 W to the coils 8 while allowing the pressure of the vacuum chamber 1 to be maintained under 0.5 Pa. In addition, boron ions in plasma could be introduced in the vicinity of the surface of the substrate 9 by supplying the high-frequency power of 250 W to the sample electrode 6. At this time, in-plane uniformity of the concentration (amount of dose) of the boron introduced in the vicinity of the surface of the substrate 9 was ±0.86%, which is a good state.

In order to make comparison, an experiment was carried out as follows. That is, the areas of the openings of the gas flow-off ports 15 were configured to be substantially equal to each other and the number of the gas flow-off ports 15 arranged to be opposed to the center portion of the sample electrode 6 was configured to be the same as that of the gas flow-off ports arranged to be opposed to the peripheral portion of the sample electrode 6. The result was that the amount of dose was larger in a portion close to the center of the substrate 9 and the in-plane uniformity was ±2.9%.

A cause of such a result will be studied. The gases flown from the gas flow-off ports arranged to be opposed to the peripheral portion of the sample electrode diffuse and disappear more outside than the peripheral portion of the substrate and also prevents the gases flown from the gas flow-off port arranged to be opposed to the center portion of the sample electrode from diffusing to the peripheral portion of the substrate. As a result, more boron-based radicals are supplied to the center portion of the substrate and more boron is also supplied to the center portion of the substrate.

Alternatively, in Embodiment 1 according to the invention, the areas of the openings of the gas flow-off ports 15 are substantially equal to each other and the number of the gas flow-off ports 15 arranged to be opposed to the center portion of the sample electrode 6 is the same as that of the gas flow-off ports 15 arranged to be opposed to the peripheral portion of the sample electrode 6. Accordingly, the gases flown from the gas flow-off ports arranged to be opposed to the peripheral portion of the sample electrode 6 diffuse and disappear outside the peripheral portion of the substrate 9, but an amount of gas flown from the gas flow ports 15 arranged to be opposed to the center portion of the sample electrode 6 is small. As a result, it is considered that the supply of the boron-based radicals in the center portion of the substrate 9 is appropriately balanced with the supply of the boron-based radicals in the peripheral portion of the substrate 9 and boron can be uniformly introduced into the surface of the substrate 9.

Such a circumstance is a specific phenomenon of a plasma doping. In a dry etching, radicals required to excite an ion assisted reaction is quite small. Accordingly, when a high-density plasma source such as the inductively coupled plasma source is used, it is rarely that uniformity of etching velocity distribution is considerably damaged due to the arrangement of the gas flow ports. In addition, in a plasma CVD, a thin film is deposited on a surface during heat of a substrate. Accordingly, as long as a temperature of the substrate is uniform, it is rarely that uniformity of deposition velocity distribution is considerably damaged due to the arrangement of the gas flow ports.

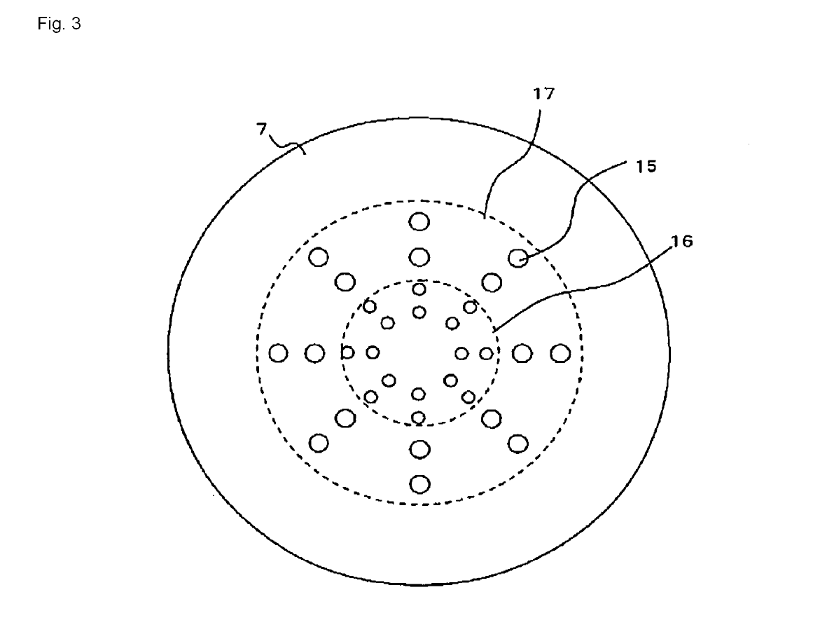

According to various experiments, it was found that a sum of the areas of the openings of the gas flow-off ports arranged to be opposed to the center portion of the sample electrode is required to be smaller than that of the areas of the openings of the gas flow-off ports arranged to be opposed to the peripheral portion of the sample electrodes in order to ensure uniformity of the amount of dose in the plasma doping. In order to realize such a circumstance, in the above-described configuration, the areas of the openings of the gas flow-off ports were configured to be each substantially equal to each other and the number of the gas flow-off ports arranged to be opposed to the center portion of the sample electrode is smaller than that of the gas flow-off ports arranged to be opposed to the peripheral portion of the sample electrode. As shown in FIG. 3, the number of the gas flow-off ports arranged to be opposed to the center portion of the sample electrode may be configured to be the same as that of the gas flow-off ports arranged to be opposed to the peripheral portion of the sample electrode. In addition, the areas of the openings of the gas flow-off ports arranged to be opposed to the center portion of the sample electrodes may be configured to be smaller than that of the openings of the gas flow-off ports arranged to be opposed to the peripheral portion of the sample electrode.

When the sum of the areas of the openings of the gas flow-off ports arranged to be opposed to the center portion of the sample electrode was a half or less than that of the areas of the openings of the gas flow-off ports arranged to be opposed to the peripheral portion of the sample electrode, that is, when mass flow of gas flown toward the center portion of the sample was a half or less than that of gas flown toward the peripheral portion of the sample, it was experimentally confirmed that good uniformity can be obtained. In this case, even when the gas flow-off port was not arranged to be opposed to the center portion of the sample electrode, there was a condition where the good uniformity was obtained.

### Embodiment 2

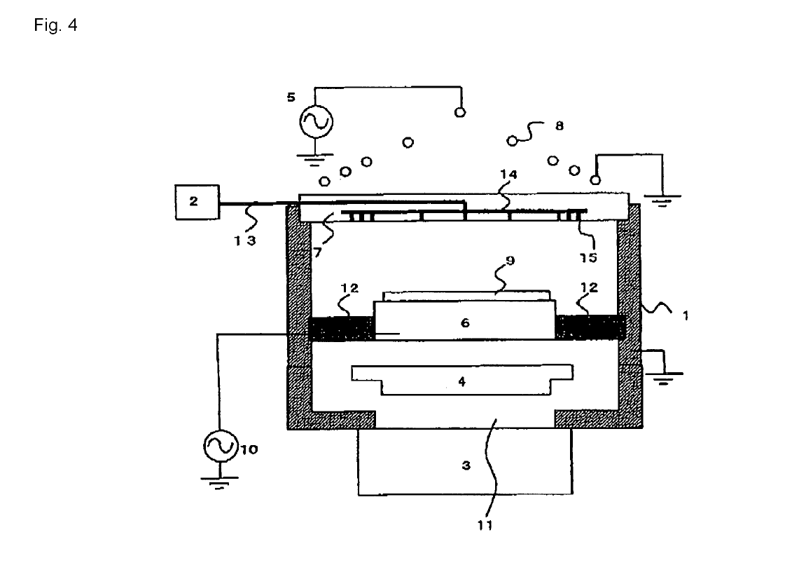

Hereinafter, Embodiment 2 of the invention will be described with reference to FIGS. 4 to 6.

FIG. 4 is a sectional view illustrating a configuration of a plasma doping apparatus according to Embodiment 2 of the invention. In FIG. 4, predetermined gases are introduced into a vacuum chamber 1 from a gas supply device 2 while the gases are evacuated by turbo-molecular a pump 3, which is an exhaust device. In addition, the vacuum chamber 1 can be maintained under a predetermined pressure by a pressure adjusting valve 4. An inductively coupled plasma can be generated by supplying high-frequency power of 13.56 MHz to coils 8 provided in the vicinity of a dielectric window 7 opposed to a sample electrode 6 by a high-frequency power source 5. A silicon substrate 9, which is a sample, is placed on the sample electrode 6. There is provided a high-frequency power source 10 for supplying high-frequency power to the sample electrode 6, which functions as a voltage source for controlling a potential of the sample electrode 6 so as to allow the substrate 9, which is a sample, to have a negative potential relative to a plasma. In this way, impurities can be introduced into a surface of the sample by accelerating ions in plasma toward the surface of the sample to collide with the surface of the sample. Gases supplied from the gas supply device 2 are evacuated from an exhaust port 11 to the pump 3. The turbo-molecular pump 3 and the exhaust port 11 are disposed right below the sample electrode 6. The pressure adjusting valve 4 is an elevation valve which is disposed right below the sample electrode 6 and right above the turbo-molecular pump 3. The sample electrode 6, which serves as a substantial rectangle-shaped seat, allows the substrate 9 to be placed thereon and each side thereof is fixed on the vacuum chamber 1 by the supports 12, that is, the sample electrode 6 is fixed on the vacuum chamber 1 by the total 4 supports 12.

A mass flow control device (mass flow controller), which is disposed in the gas supply device 2, controls mass flow of gas including impurity material gases to be under a predetermined value. Generally, gases diluted with helium, that is, the gases generated by diluting, for example, diborane (B₂H₆) with helium (He) by 0.5% are used as impurity material gases, which are controlled by a first mass flow controller. A mass flow of helium is controlled by the second mass flow controller, the mass flow of gas controlled by the first and second mass flow controllers are mixed in the gas supply device 2 and guided to the gas primary passage 14 through a pipe (gas introducing passage) 13, and the mixed gases are guided from the gas flow-off ports 15 to the inside of the vacuum chamber 1 through a plurality of holes communicating with the gas primary passage 14. A plurality of gas flow-off ports 15 are configured to flow off gases toward the sample 9 from a surface opposite the sample 9.

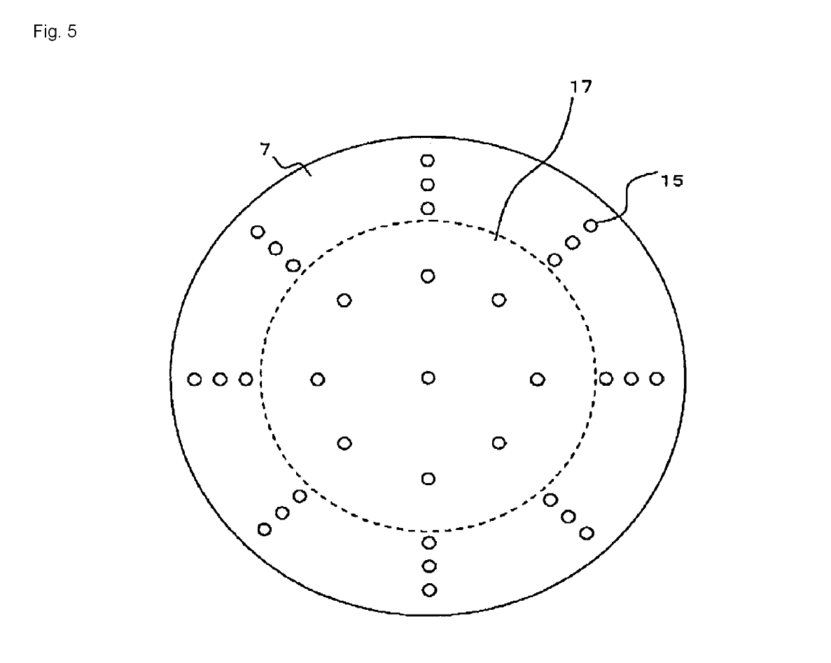

FIG. 5 is a top view illustrating the dielectric window 7 when viewed from a lower side in FIG. 4. As shown in FIG. 5, the gas flow-off ports 15 are arranged so as to be substantially symmetric about the center of the dielectric window 7 and configured so as to flow off the gases substantially isotropically toward the sample. That is, the plurality of gas flow-off ports 15 are arranged substantially isotropically. The gas flow-off ports arranged to be opposed to the center portion of the sample electrode are considered to be the gas flow-off ports (9 ports) arranged in the inside of a circle 17 (which is a circle with the same diameter as that of the sample). In addition, the gas flow-off ports arranged to be opposed to the peripheral portion of the sample (electrode) are considered to be the gas flow-off ports (24 ports) arranged in the inside of the outer circle 17 (which is a circle with the same diameter as that of the sample) and the outside of the circle 17. In this way, areas of openings of the gas flow-off ports 15 are configured so as to be substantially equal to each other and the number of the gas flow-off ports 15 arranged to be opposed to the center portion of the sample electrode 6 is smaller than that of the flow-off ports arranged to be opposed to the peripheral portion of the sample electrode 6. Accordingly, the mass flow of gas flown toward the center portion of the sample 9 can be smaller than that of gas flown toward the peripheral portion of the sample 9.

The plasma was generated in the vacuum chamber 1 by supplying B₂H₆ gases of 5 sccm diluted with He and He gases of 100 sccm while allowing a temperature of the sample electrode 6 to be maintained at 25° C. and supplying high-frequency power of 1300 W to the coils 8 while allowing the pressure of the vacuum chamber 1 to be maintained under 0.5 Pa. In addition, boron ions in plasma could be introduced in the vicinity of the surface of the substrate 9 by supplying the high-frequency power of 250 W to the sample electrode 6. At this time, in-plane uniformity of the concentration (amount of dose) of the boron introduced in the vicinity of the surface of the substrate 9 was ±0.75%, which is a good state.

In order to make comparison, an experiment was carried out as follows. That is, the areas of the openings of the gas flow-off ports 15 were configured to be substantially equal to each other and the number of the gas flow-off ports 15 arranged to be opposed to the center portion of the sample electrode 6 was configured to be the same as that of the gas flow-off ports arranged to be opposed to the peripheral portion of the sample electrode 6. The result was that the amount of dose was larger in a portion close to the center of the substrate 9 and the in-plane uniformity was ±3.4%.

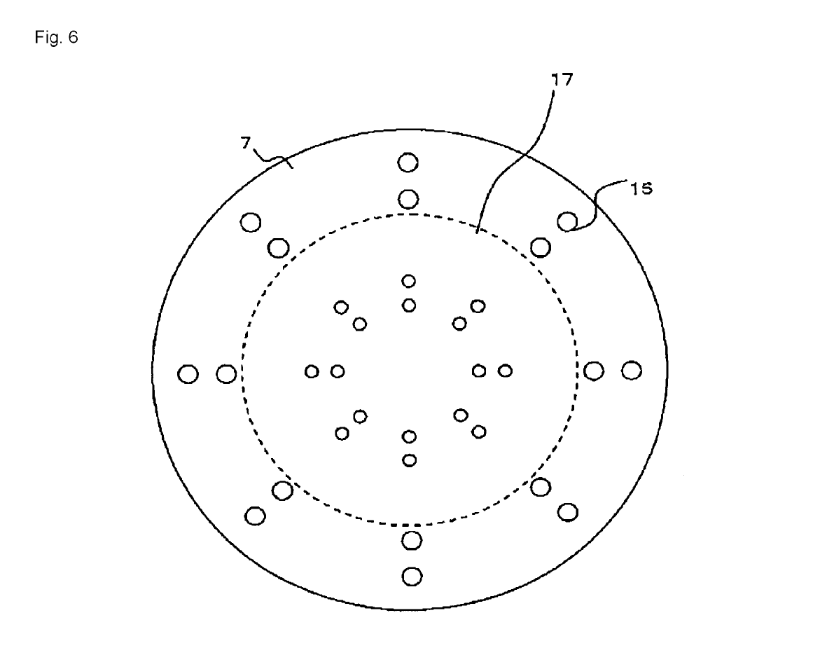

According to various experiments, it was found that a sum of the areas of the openings of the gas flow-off ports arranged to be opposed to the center portion of the sample electrode is required to be smaller than that of the areas of the openings of the gas flow-off ports arranged to be opposed to the peripheral portion of the sample electrodes in order to ensure uniformity of the amount of dose in the plasma doping. In order to realize such a circumstance, in the above-described configuration, the areas of the openings of the gas flow-off ports were configured to be each substantially equal to each other and the number of the gas flow-off ports arranged to be opposed to the center portion of the sample electrode is smaller than that of the gas flow-off ports arranged to be opposed to the peripheral portion of the sample electrode. As shown in FIG. 6, the number of the gas flow-off ports arranged to be opposed to the center portion of the sample electrode may be configured to be the same as that of the gas flow-off ports arranged to be opposed to the peripheral portion of the sample electrode. In addition, the areas of the openings of the gas flow-off ports arranged to be opposed to the center portion of the sample electrodes may be configured to be smaller than that of the openings of the gas flow-off ports arranged to be opposed to the peripheral portion of the sample electrode.

When the sum of the areas of the openings of the gas flow-off ports arranged to be opposed to the sample electrode was a half or less than that of the areas of the openings of the gas flow-off ports arranged to be opposed to the outside of the sample electrode, that is, when mass flow of gas flown toward the sample was a half or less than that of gas flown toward the outside of the sample in the surface on which the sample is placed, it was experimentally confirmed that good uniformity can be obtained. In this case, even when the gas flow-off port was not arranged to be opposed to the center portion of the sample electrode, there was a condition where the good uniformity was obtained.

### Embodiment 3

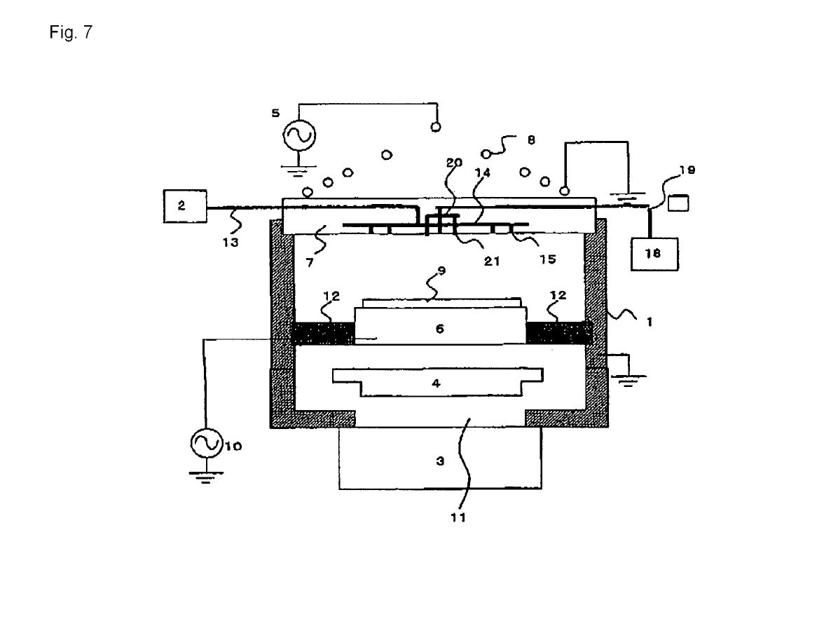

Hereinafter, Embodiment 3 of the invention will be described with reference to FIG. 7.

FIG. 7 is a sectional view illustrating a configuration of a plasma doping apparatus according to Embodiment 3 of the invention. In FIG. 7, predetermined gases are introduced into a vacuum chamber 1 from a first gas supply device 2 and a second gas supply device 18 while the gases are evacuated by turbo-molecular a pump 3, which is an exhaust device. In addition, the vacuum chamber 1 can be maintained under a predetermined pressure by a pressure adjusting valve 4. An inductively coupled plasma can be generated by supplying high-frequency power of 13.56 MHz to coils 8 provided in the vicinity of a dielectric window 7 opposed to a sample electrode 6 by a high-frequency power source 5. A silicon substrate 9, which is a sample, is placed on the sample electrode 6. There is provided a high-frequency power source 10 for supplying high-frequency power to the sample electrode 6, which functions as a voltage source for controlling a potential of the sample electrode 6 so as to allow the substrate 9, which is a sample, to have a negative potential relative to a plasma. In this way, impurities can be introduced into a surface of the sample by accelerating ions in plasma toward the surface of the sample to collide with the surface of the sample. Gases supplied from the first gas supply device 2 and the second gas supply device 18 are evacuated from an exhaust port 11 to the pump 3. The turbo-molecular pump 3 and the exhaust port 11 are disposed right below the sample electrode 6. The pressure adjusting valve 4 is an elevation valve which is disposed right below the sample electrode 6 and right above the turbo-molecular pump 3. The sample electrode 6, which serves as a substantial rectangle-shaped seat, allows the substrate 9 to be placed thereon and each side thereof is fixed on the vacuum chamber 1 by supports 12, that is, the sample electrode 6 is fixed on vacuum chamber 1 by the total 4 supports 12.

A mass flow control device (mass flow controller), which is disposed in the first gas supply device 2, controls mass flow of gas including impurity material gases to be under a predetermined value. Generally, gases diluted with helium, that is, the gases generated by diluting, for example, diborane (B₂H₆) with helium (He) by 0.5% are used as impurity material gases, which are controlled by a first mass flow controller. A mass flow of helium is controlled by the second mass flow controller, the mass flow of gas controlled by the first and second mass flow controllers are mixed in the gas supply device 2 and guided to the gas primary passage 14 through a pipe 13, and the mixed gases are guided from the gas flow-off ports 15 to the inside of the vacuum chamber 1 through a plurality of holes communicating with the gas primary passage 14. A plurality of gas flow-off ports 15 are configured to flow off gases toward the sample 9 from a surface opposite the sample 9.

A mass flow control device (mass flow controller), which is disposed in the second gas supply device 18, controls the mass flow of gas including the impurity material gases to be under a predetermined value. Generally, gases diluted with helium, that is, the gases generated by diluting, for example, diborane (B₂H₆) with helium (He) by 0.5% are used as the impurity material gases, which are controlled by a third mass flow controller. A mass flow of helium is controlled by a fourth mass flow controller, the mass flow of gas controlled by the third and fourth mass flow controllers are mixed in the second gas supply device 18 and guided to a gas primary passage 20 through a pipe 19, and the mixed gases are guided from gas flow-off ports 21 to the inside of the vacuum chamber 1 through a plurality of holes communicating with the gas primary passage 20. A plurality of gas flow-off ports 21 are configured to flow off gases toward the center portion of the sample 9 from a surface opposite the sample 9.

The plasma was generated in the vacuum chamber 1 by supplying B₂H₆ gases of 1 sccm diluted with He and He gases of 50 sccm from the first gas supply device 2 while allowing a temperature of the sample electrode 6 to be maintained at 25° C., supplying B₂H₆ gases of 4 sccm diluted with He and He gases of 50 sccm from the second gas supply device 18 and supplying high-frequency power of 1300 W to the coils 8 while allowing the pressure of the vacuum chamber 1 to be maintained under 0.5 Pa. In addition, boron ions in plasma could be introduced in the vicinity of the surface of the substrate 9 by supplying the high-frequency power of 250 W to the sample electrode 6. At this time, in-plane uniformity of the concentration (amount of dose) of the boron introduced in the vicinity of the surface of the substrate 9 was ±0.68%, which is a good state.

In order to make comparison, an experiment was carried out under the condition that the concentrations of the impurity material gases including the gases supplied from the first supply device 2 and the second supply device 18 are equal to each other, that is, the mass flow of impurity material gas included in the gases flown toward the center portion of the sample is equal to that of the impurity material gases included in the gases flown toward the peripheral portion of the sample. The result was that the amount of dose was larger in a portion close to the center of the substrate 9 and the in-plane uniformity was ±2.7%.

According to various experiments, in order to ensure uniformity of the amount of dose in the plasma doping, it was found that the following configuration is required. That is, it is required that the gas flow-off ports 15 and 21 are arranged so as to be substantially symmetric about the center of the dielectric window 7 and configured so as to flow off the gases substantially isotropically toward the sample, that is, the plurality of gas flow-off ports 15 and 21 are arranged substantially isotropically. Moreover, when “a center portion of the sample (electrode)” is defined as “a portion of which an area is a half of that of the sample (electrode) and which includes the center of the sample (electrode)” and “a peripheral portion of the sample (electrode)” is defined as “a portion which is the other portion of the sample (electrode) and which does not include the center of the sample (electrode), it is required that the mass flow of impurity material gas included in the gases flown toward to the center portion of the sample is smaller than that of the impurity material gases included in gases flown toward the peripheral portion of the sample.

When the mass flow of impurity material gas included in the gases flown toward the center portion of the sample was a half or less than that of the impurity material gases included in the gases flown toward the peripheral portion of the sample, it was experimentally confirmed that good uniformity can be obtained.

### Embodiment 4

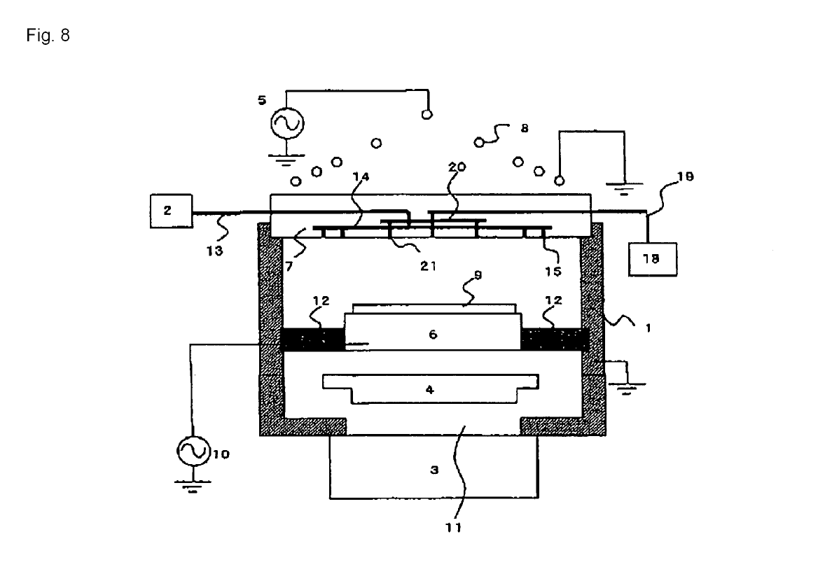

Hereinafter, Embodiment 4 of the invention will be described with reference to FIG. 8.

FIG. 8 is a sectional view illustrating a configuration of a plasma doping apparatus according to Embodiment 4 of the invention. In FIG. 7, predetermined gases are introduced into a vacuum chamber 1 from a first gas supply device 2 and a second gas supply device 18 while the gases are evacuated by turbo-molecular a pump 3, which is an exhaust device. In addition, the vacuum chamber 1 can be maintained under a predetermined pressure by a pressure adjusting valve 4. An inductively coupled plasma can be generated by supplying high-frequency power of 13.56 MHz to coils 8 provided in the vicinity of a dielectric window 7 opposed to a sample electrode 6 by a high-frequency power source 5. A silicon substrate 9, which is a sample, is placed on the sample electrode 6. There is provided a high-frequency power source 10 for supplying high-frequency power to the sample electrode 6, which functions as a voltage source for controlling a potential of the sample electrode 6 so as to allow the substrate 9, which is a sample, to have a negative potential relative to a plasma. In this way, impurities can be introduced into a surface of the sample by accelerating ions in plasma toward the surface of the sample to collide with the surface of the sample. Gases supplied from the first gas supply device 2 and the second gas supply device 18 are evacuated from an exhaust port 11 to the pump 3. The turbo-molecular pump 3 and the exhaust port 11 are disposed right below the sample electrode 6. The pressure adjusting valve 4 is an elevation valve which is disposed right below the sample electrode 6 and right above the turbo-molecular pump 3. The sample electrode 6, which serves as a substantial rectangle-shaped seat, allows the substrate 9 to be placed thereon and each side thereof is fixed on the vacuum chamber 1 by supports 12, that is, the sample electrode 6 is fixed on the vacuum chamber 1 by the total 4 supports 12.

A mass flow control device (mass flow controller), which is disposed in the first gas supply device 2, controls mass flow of gas including impurity material gases to be under a predetermined value. Generally, gases diluted with helium, that is, the gases generated by diluting, for example, diborane (B₂H₆) with helium (He) by 0.5% are used as impurity material gases, which are controlled by a first mass flow controller. A mass flow of helium is controlled by the second mass flow controller, the mass flow of gas controlled by the first and second mass flow controllers are mixed in the gas supply device 2 and guided to a gas primary passage 14 through a pipe 13, and the mixed gases are guided from gas flow-off ports 15 to the inside of the vacuum chamber 1 through a plurality of holes communicating with the gas primary passage 14. A plurality of gas flow-off ports 15 are configured to flow off gases toward the sample 9 from a surface opposite the sample 9.

A mass flow control device (mass flow controller), which is disposed in the second gas supply device 18, controls the mass flow of gas including the impurity material gases to be under a predetermined value. Generally, gases diluted with helium, that is, the gases generated by diluting, for example, diborane (B₂H₆) with helium (He) by 0.5% are used as the impurity material gases, which are controlled by a third mass flow controller. A mass flow of helium is controlled by a fourth mass flow controller, the mass flow of gas controlled by the third and fourth mass flow controllers are mixed in the second gas supply device 18 and guided to a gas primary passage 20 through a pipe 19, and the mixed gases are guided from gas flow-off ports 21 to the inside of the vacuum chamber 1 through a plurality of holes communicating with the gas primary passage 20. A plurality of gas flow-off ports 21 are configured to flow off gases toward the center portion of the sample 9 from a surface opposite the sample 9.

The plasma was generated in the vacuum chamber 1 by supplying B₂H₆ gases of 1 sccm diluted with He and He gases of 50 sccm from the first gas supply device 2 while allowing a temperature of the sample electrode 6 to be maintained at 25° C., supplying B₂H₆ gases of 4 sccm diluted with He and He gases of 50 sccm from the second gas supply device 18 and supplying high-frequency power of 1300 W to coils 8 while allowing the pressure of the vacuum chamber 1 to be maintained under 0.5 Pa. In addition, boron ions in plasma could be introduced in the vicinity of the surface of the substrate 9 by supplying the high-frequency power of 250 W to the sample electrode 6. At this time, in-plane uniformity of the concentration (amount of dose) of the boron introduced in the vicinity of the surface of the substrate 9 was ±0.72%, which is a good state.

In order to make comparison, an experiment was carried out under the condition that the concentrations of the impurity material gases including the gases supplied from the first supply device 2 and the second supply device 18 are equal to each other, that is, the mass flow of impurity material gas included in the gases flown toward the center portion of the sample is equal to that of the impurity material gases included in the gases flown toward the peripheral portion of the sample. The result was that the amount of dose was larger in a portion close to the center of the substrate 9 and the in-plane uniformity was ±2.8%.

According to various experiments, in order to ensure uniformity of the amount of dose in the plasma doping, it was found that the following configuration is required. That is, it is required that the gas flow-off ports 15 and 21 are arranged so as to be substantially symmetric about the center of a dielectric window 7 and configured so as to flow off the gases substantially isotropically toward the sample, that is, the plurality of the gas flow-off ports 15 and 21 are arranged substantially isotropically. Moreover, it is required that the mass flow of impurity material gas included in the gases flown toward to the sample is smaller than that of the impurity material gases included in gases flown toward the outside of the sample in the surface on which the sample is placed.

When the mass flow of impurity material gas included in the gases flown toward the sample was a half or less than that of the impurity material gases included in the gases flown toward the outside of the sample on the surface on which the sample is placed, it was experimentally confirmed that good uniformity can be obtained.

The above-described embodiments are only a few of variation about a shape of a vacuum chamber, a type or arrangement of a plasma source, and the like among a scope of the present invention application. It is not necessary to say that the invention is not limited thereto, but various embodiments can be considered in the scope of the invention application.

For example, coils 8 may have a plane shape. In addition, a helicon wave plasma source, a magnetic neutral loop plasma source, microwave plasma source (electron cyclotron resonance plasmas) with a magnetic field, and a parallel-plate type plasma source may be used.

However, it is desirable that the inductively coupled plasma source is used in that the gas flow-off ports can be easily formed on a surface opposite the sample (electrode).

In addition, an inactive gas may be used in addition to helium and at least any one of neon, argon, krypton, and xenon can be used. Such inactive gases have an advantage in that a bad effect on a sample is smaller than other gases.

It is exemplified that the sample is a semiconductor substrate formed of silicon, but the invention can be applied when samples of other different materials are processed. However, the prevent invention is particularly an effective plasma doping method in a case where the sample is the semiconductor substrate formed of silicon. In addition, it is particularly effective in a case where the impurity is arsenic, phosphorous, boron, or antimony. With such a configuration, it is possible to manufacture a highly minute silicon semiconductor device.

The invention is described in detail with reference to specific embodiments, but may be modified in various forms without departing from the spirit and scope of the invention for a person skilled in the art.

This application is based on Japanese Patent Application No. 2005-099103 filed on Mar. 30, 2005, which is hereby incorporated by reference in its entirety.

### INDUSTRIAL APPLICABILITY

According to the invention, there is provided plasma doping method and apparatus capable of introducing impurities into a sample surface so that uniformity of concentration of the impurities is good.

Accordingly, the plasma doping method and apparatus is applicable to a manufacture of a thin film transistor used in a liquid crystal and the like, a surface reforming of various materials, etc.

1-8. (canceled)

9. A plasma doping method comprising the steps of:
placing a sample on a sample electrode in a vacuum chamber;
flowing a gas substantially isotropically toward the sample from a surface opposed to the sample while discharging the gas in the vacuum chamber;
generating a plasma in the vacuum chamber while controlling the vacuum chamber to be under a predetermined pressure; and
introducing impurity ions into a surface of the sample by allowing the impurity ions in the plasma to collide with the surface of the sample,
wherein a mass flow of gas flown toward a center portion of the sample and a mass flow of gas flown toward the outside of the sample in a surface on which the sample is placed are controlled by individual mass flow control systems, and
wherein a concentration of impurity material gas included in the gas flown toward the center portion of the sample is less than that of impurity material gas included in the gas flown toward the outside of the sample in the surface on which the sample is placed.

10. The plasma doping method according to claim 9, wherein the mass flow of impurity material gas included in the gas flown toward the center portion of the sample is a half or less than that of impurity material gas included in the gas flown toward the peripheral portion of the sample.

11. The plasma doping method according to claim 9, wherein plasmas are generated in the vacuum chamber by the supply of high-frequency power to a plasma source.

12. The plasma doping method according to claim 9, wherein the sample is a semiconductor substrate made of silicon.

13. The plasma doping method according to claim 9, wherein the impurity is arsenic, phosphorous, boron, or antimony.

14-24. (canceled)
